(19) United States
(12) Patent Application Publication
(10) Pub. No.: US 2026/0150670 A1
(43) Pub. Date: May 28, 2026

(54) Apparatuses and Methods to Assist in Pressure Sintering Operations

(71) Applicant: SF Motors, Inc., Milpitas, CA (US)

(72) Inventors: Gwo-Jeng LO, Cupertino, CA (US); Zhong NIE, San Carlos, CA (US); Zhichun MA, Morgan Hill, CA (US)

(73) Assignee: SF Motors, Inc., Milpitas, CA (US)

(21) Appl. No.: 18/962,568

(22) Filed: Nov. 27, 2024

(51) Int. Cl. H01L 23/367; H01L 23/00

(52) U.S. Cl. CPC H10W 40/226; H10W 72/352; H10W 90/736

(57) ABSTRACT

Apparatuses and Systems to assist in pressure sintering operations. The apparatus can include a base plate. The base plate can receive a heat sink. The base plate can include a landing zone. The landing zone can include a protrusion. The protrusion can at least partially define an opening. The opening can receive a fin of the heat sink.

### BACKGROUND

A conductive element can transfer heat to or from adjacent elements to which they are thermally coupled.

### SUMMARY

At least one aspect is directed to a sintering apparatus. The apparatus can include a base plate. The base plate can receive a heat sink. The base plate can include a landing zone. The landing zone can include a protrusion. The protrusion can at least partially define an opening. The opening can receive a fin of the heat sink.

At least one aspect is directed to a method of sintering an electronic device with a heat sink. The method can include receiving, by a base plate, the heat sink. The base plate can include a landing zone. The method can include receiving a fin of the heat sink. The fin can be received by an opening at least partially defined by a protrusion of the landing zone.

At least one aspect is directed to a heat sink. The heat sink can include a rib. A section can be at least partially defined by the rib. The section can include a first area and a second area. The first area can be thicker than the second area.

At least one aspect is directed to a method. The method can include providing a heat sink. The heat sink can include a rib. The heat sink can include a section. The section can be at least partially defined by the rib. The section can include a first area and a second area. The first area can be thicker than the second area.

At least one aspect is directed to a sintering apparatus. The sintering apparatus can include a press tool. The press tool can include a body. The press tool can include a protrusion. The press tool can include a fiber-reinforced polymer cap coupled with the protrusion. The fiber-reinforced polymer cap can contact an electronic device to sinter the electronic device with a heat sink.

At least one aspect is directed to a method of sintering an electronic device. The method can include sintering, by a press tool, an electronic device with a heat sink. The press tool can include a body. The press tool can include a protrusion. The press tool can include a fiber-reinforced polymer cap coupled with the protrusion. The fiber-reinforced polymer cap can contact the electronic device to sinter the electronic device with the heat sink.

### BRIEF DESCRIPTION OF THE DRAWINGS

The accompanying drawings are not intended to be drawn to scale. Like reference numbers and designations in the various drawings indicate like elements. For purposes of clarity, not every component can be labeled in every drawing. In the drawings:

FIG. 1 depicts an example system to assist in pressure sintering.

FIG. 2 depicts an example system to assist in pressure sintering.

FIG. 3 depicts an example system to assist in pressure sintering.

FIG. 4 depicts an example system to assist in pressure sintering.

FIG. 5 depicts an example system to assist in pressure sintering.

FIG. 6 depicts an example sintering apparatus.

FIG. 7 depicts an example sintering apparatus.

FIG. 8 depicts an example sintering apparatus.

FIG. 9 depicts an example heat sink.

FIG. 10 depicts an example heat sink.

FIG. 11 depicts an example heat sink.

FIG. 12 depicts a sintering apparatus.

FIG. 13 depicts a sintering apparatus.

FIG. 14 depicts a sintering apparatus.

FIG. 15 depicts a sintering apparatus.

FIG. 16 depicts an example method of sintering an electronic device with a heat sink.

FIG. 17 depicts an example method of providing a heat sink.

FIG. 18 depicts an example method of sintering an electronic device.

### DETAILED DESCRIPTION

Following below are more detailed descriptions of various concepts related to, and implementations of an apparatus for assisting in pressure sintering operations. The various concepts introduced above and discussed in greater detail below can be implemented in any of numerous ways.

Apparatuses and methods described herein relate to pressure sintering an electronic device to a heat sink. A consistent and even pressure applied to the electronic devices can be beneficial for efficient pressure sintering operations. However, electronic devices come in a variety of package types and, by extension, a variety of different dimensions. For example, one electronic device may have a different height that a second electronic device. This can create challenges in creating a single device that can simultaneously sinter multiple electronic devices of different heights.

To resolve these and other challenges, apparatuses, and methods to assist in pressure sintering operations are described herein. A first apparatus to assist in the pressure sintering operations can include a sintering apparatus. The apparatus can include a base plate to receive a heat sink. The base plate can include a landing zone. The landing zone can include a protrusion that can at least partially define an opening to receive a fin of the heat sink. The gaps of the base plate receiving a fin of the heat sink prevent the heat sink from moving and deforming during the pressure sintering apparatus, resulting in a more consistent and even pressure being applied to the electronic devices.

A second apparatus can include a heat sink. The heat sink can include a rib. The heat sink can include a section at least partially defined by the rib. The section can include a first area and a second area, the first area thicker than the second area. The first area being thicker than the second area can increase the stiffness of the heat sink, which can reduce damage to the heat sink during the pressure sintering operations. In addition, the heat sink can improve the uniformity of the pressure being applied to the electronic devices without reducing the thermal performance of the heat sink.

A third apparatus can include a sintering apparatus. The sintering apparatus can include a press tool. The press tool can include a body and a protrusion. The body can include a fiber-reinforced polymer cap coupled with the protrusion. The fiber-reinforced polymer cap can contact an electronic device to sinter the electronic device with a heat sink. The fiber-reinforced polymer cap can be soft enough to prevent damaging the electronic device, but hard enough to apply a steady pressure to the electronic device. The fiber-reinforced polymer can compress to manage various heights of electronic devices. For example, the fiber-reinforced polymer can compress more for a taller electronic device than a shorter electronic device, while simultaneously applying a constant pressure to both devices.

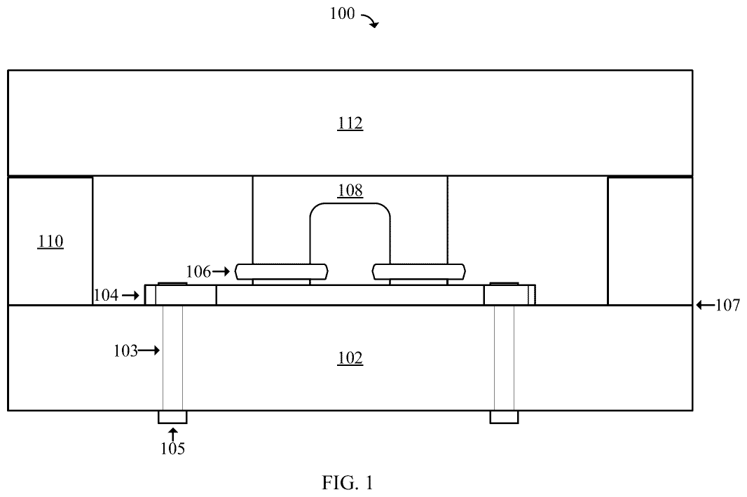

FIG. 1, among others, depicts an example of a system 100 to assist in pressure sintering. System 100 can include at least one base plate 102. Base plate 102 can receive at least one heat sink 104. Base plate 102 can act as a solid surface for heat sink 104 to rest on during the pressure sintering operations. Base plate 102 can be larger than heat sink 104 to ensure the entirety of heat sink 104 is in contact with base plate 102.

A paste can be disposed between heat sink 104 an electronic device 106. For example, the paste can include a metal-based powder, a ceramic-based powder, or a composite power including one or more metal based powders or ceramic base powders. More specifically, the paste can be a silver paste made of a silver powder.

System 100 can include at least one aperture 103. For example, base plate 102 can include at least one aperture 103. Aperture 103 can traverse through base plate 102. Aperture 103 can receive at least one fastener 105 to couple base plate 102 with heat sink 104 for the pressure sintering operations. For example, base plate 102 can include a first aperture 103 to receive a first fastener 105 to couple base plate 102 with heat sink 104. Base plate 102 can also include a second aperture 103 to receive a second fastener 105 to couple base plate 102 with heat sink 104.

System 100 can include at least one heat sink 104. Heat sink 104 can be made of a variety of thermally conductive materials. For example, heat sink 104 can be made of aluminum, copper, graphite, ceramics, for example. System 100 can sinter at least one electronic device 106 to heat sink 104. Heat sink 104 can be sintered to electronic device 106 to dissipate heat built up by electronic device 106 and other devices coupled with electronic device 106 during operation of said devices. Dissipating the heat enables electronic device 106 to operate more efficiently and prevent damage from high heat. Heat sink 104 can be sized proportionately to the number of electronic devices 106. For example, a heat sink 104 sized to fix two electronic devices 106 can be smaller than a heat sink 104 sized to fit 6 electronic devices 106.

Heat sink 104 can include a first heat sink 104 and a second heat sink 104. First heat sink 104 and second heat sink 104 can both be coupled with base plate 102. First heat sink 104 and second heat sink 104 can include different materials. For example, first heat sink 104 can include aluminum and second heat sink 104 can include ceramics. First heat sink 104 can receive a first electronic device 106 and second heat sink 104 can receive a second electronic device 106.

System 100 can include at least one electronic device 106. Electronic device 106 can be a variety of electrical components. Electronic device 106 can be power devices, transistors, resistors, capacitors, inductors, diodes, for example. For example, electronic device 106 can be a power device composed of silicon carbide, or a SiC (Silicon Carbide) power device. Electronic device 106 can come in a variety of package dimensions. For example, electronic device 106 can have a height between 2 mm to 6 mm and a width or length between 25 mm and 55 mm. Electronic device 106 can have one or more leads to couple electronic device 106 with other devices or a larger electrical system and to allow current to flow therein.

Electronic device 106 can include a first electronic device 106 and a second electronic device 106. First electronic device 106 can be a different electrical component than second electronic device 106. For example, first electronic device 106 can include a diode and second electronic device 106 can include a SiC power device. First electronic device 106 and second electronic device 106 can have different package dimensions. For example, first electronic device 106 can include a height of 3 mm and a width and a length of 30 mm. Second electronic device 106 can include a height of 5 mm and a width and a length of 45 mm. First electronic device 106 can include a height of between 1 and 5 mm and a width and a length of between 20-40 mm. Second electronic device 106 can include a height of between 2-8 mm and a width and a length of 35-55 mm. Other example ranges greater than and less than this range are possible.

System 100 can include at least one press tool 108. Press tool 108 can sinter electronic device 106 with heat sink 104. Electronic device 106 can be sintered to at least one surface of heat sink 104. For example, press tool 108 can apply a pressure to the top of electronic device 106 resulting in the pressure being applied to the green body, heat sink 104, and base plate 102. The pressure applied by press tool 108 can compact the green body to form a compact material and couple electronic device 106 with heat sink 104. Press tool 108 can be coupled with at least one plate 112.

System 100 can include at least one plate 112. Plate 112 can raise or lower press tool 108 to come into contact with electronic device 106. Plate 112 can lower press tool 108 until coming into contact with at least one stopper 110. Once coming into contact with stopper 110, plate 112 cannot continue to lower, but press tool 108 can continue to apply pressure to electronic device 106.

System 100 can include at least one stopper 110. Stopper 110 can be coupled with base plate 102. Stopper 110 can stop plate 112 from lowering toward electronic device 106 past the height of stopper 110. Stopper 110 can be disposed along at least one edge 107 of base plate 102. For example, base plate 102 can be a rectangular prism with a stopper 110 disposed on each edge 107 of the topmost face of base plate 102.

Base plate 102, heat sink 104, press tool 108, stoppers 110, and plate 112 can be a variety of shapes. For example, Base plate 102, heat sink 104, press tool 108, stoppers 110, and plate 112 can be a regular polyhedral solid (e.g., a cube, a tetrahedron, etc.) including one or more flat polygonal faces, straight edges, and vertices. Base plate 102, heat sink 104, press tool 108, stoppers 110, and plate 112 can be symmetrical or asymmetrical, and can include an irregular polyhedral solid including one or more faces of a first shape and one or more faces of a second shape, such as an irregular pyramid with one or more faces that are triangular and one or more faces that are rectangular. Base plate 102, heat sink 104, press tool 108, stoppers 110, and plate 112 can be a non-polyhedral solid (e.g., a sphere, an ellipsoid, a cylinder, etc.) including one or more curved surfaces or edges. For example, base plate 102 and stoppers 110 can be cylinders, heat sink 104 and plate 112 can be a rectangular prism, and press tool can be an irregular polyhedral solid.

Base plate 102, heat sink 104, press tool 108, stoppers 110, and plate 112 can include one or more materials. The one or more materials can include various metals (e.g., aluminum, alloy steel, tin, etc.), non-metals, woods, polymers, for example. For example, base plate 102 can be made of wood, stoppers 110 can be made of a plastic, and plate 112 can be made of aluminum.

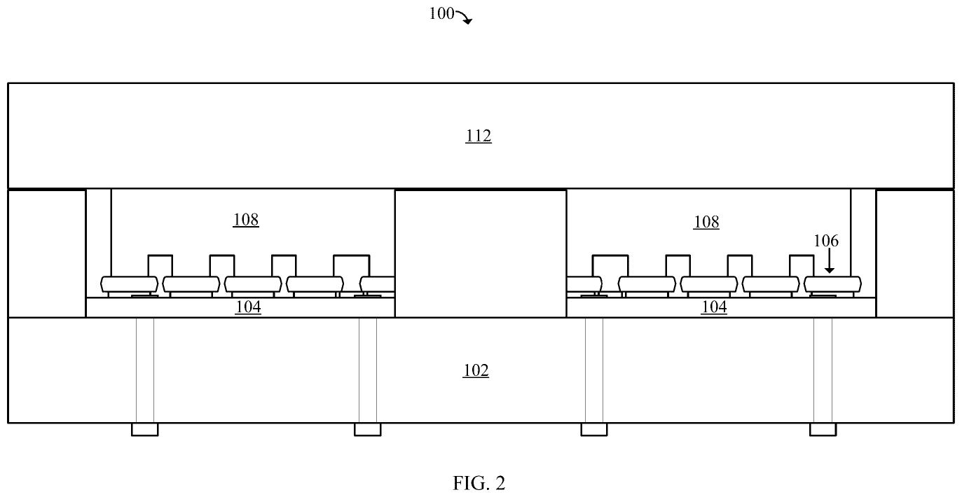

FIG. 2, among others, depicts an example of system 100 to assist in pressure sintering. First heat sink 104 and second heat sink 104 can both be coupled with base plate 102. Plate 112 can lower press tool 108 to sinter one or more electronic devices 106 to first heat sink 104 and second heat sink 104. For example, press tool 108 can simultaneously sinter a first electronic device 106 to first heat sink 104 and second electronic device 106 to second heat sink 104.

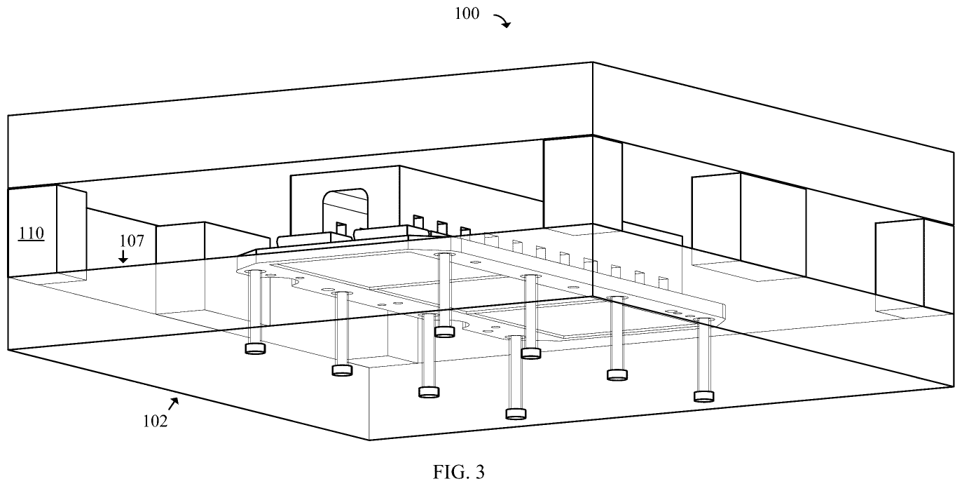

FIG. 3, among others, depicts an example of system 100 to assist in pressure sintering. Each edge 107 of base plate 102 can be coupled with one or more stoppers 110. For example, a first edge 107 and a second edge 107 can each be coupled with three stoppers 110, first edge 107 can be opposite second edge 107. A third edge 107 and a fourth edge 107 can be coupled with two stoppers 110, third edge 107 can be opposite fourth edge 107. One or more stoppers 110 can be coupled with two edges 107. For example, one stopper 110 can be coupled to a corner of base plate 102 and can be shared by the first edge 107 and the third edge 107.

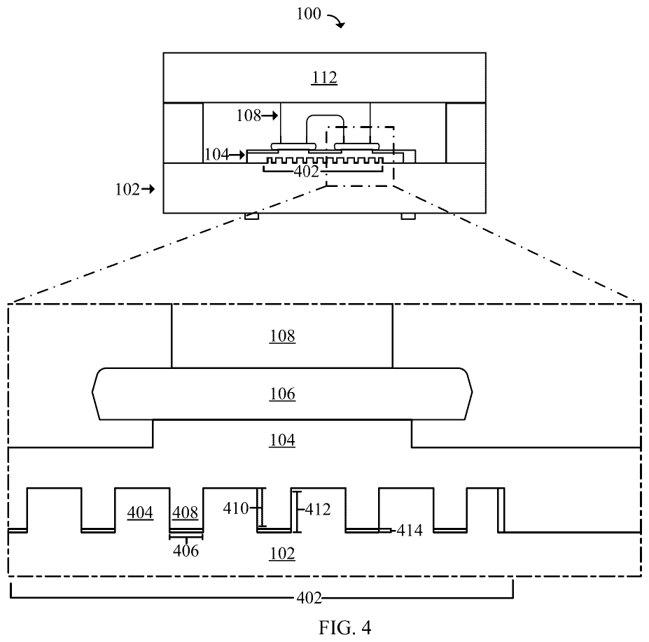

FIG. 4, among others, depicts an example of system 100 to assist in pressure sintering. Base plate 102 can have at least one landing zone 402. Landing zone 402 can take up at least part of one or more faces of base plate 102. For example, landing zone 402 can make up between a tenth to a half of the surface area of a face of base plate 102. Landing zone 402 can also make up more or less of the surface area than in this range. Landing zone 402 can extend from at least one face of base plate 102. For example, landing zone 402 can extend between a height of 1 mm to 6 mm off of base plate 102 (as well as heights greater than or less than this range). Landing zone 402 can be flush with base plate 102.

Landing zone 402 can include a first landing zone 402 and a second landing zone 402. First landing zone 402 and second landing zone 402 can be a part of the same base plate 102. First landing zone 402 and second landing zone 402 can be a part of the same face of base plate 102. For example, first landing zone 402 and second landing zone 402 can both be disposed along the top face of base plate 102.

First landing zone 402 and second landing zone 402 can make up different amounts of the surface area of base plate 102. For example, first landing zone 402 can make up a tenth of the surface area of base plate 102 and second landing zone 402 can make up a quarter of the surface area of base plate 102. Landing zone 402 and second landing zone 402 can extend to different heights off base plate 102. For example, first landing zone 402 can extend 2 mm off base plate 102 and second landing zone 402 can extend 5 mm off base plate 102.

Landing zone 402 can include at least one protrusion 404. Protrusion 404 can include a height between 1 mm and 6 mm (as well as a height greater than or less than this range). The height of the protrusion 404 can be measured from where protrusion 404 begins along base plate 102 or landing zone 402 to the tallest point of protrusion 404. For example, landing zone 402 can have a height of 1-4 mm (e.g., 2 mm) from base plate 102 and protrusion 404 can have a height of 0.5-2.0 (e.g., 1 mm) from landing zone 402. Therefore, measuring from the top of base plate 102 to the tallest point of protrusion 404 can have a height of 1-5 mm (e.g., 3 mm).

Protrusion 404 can include various shapes. For example, the cross-sectional area of protrusion 404 can include a polygon (e.g., triangle, square, rectangle, pentagon, etc.), a circle, an ellipsis, or a complex shape (e.g., a star, an irregular shape, etc.). Protrusion 404 can include one or more edges. The edges can include straight and curved edges. For example, protrusion 404 can include a straight edge and a curved edge opposite the straight edge.

Protrusion 404 can include a first protrusion 404 and a second protrusion 404. First protrusion 404 and second protrusion 404 can be a part of first landing zone 402. First protrusion 404 can be a part of a first landing zone 402 and second protrusion 404 can be a part of a second landing zone 402. First protrusion 404 can have a height different than or the same as the height of second protrusion 404. For example, first protrusion 404 can have a height of 2 mm and second protrusion 404 can have a height of 3 mm. First protrusion 404 can have a cross-sectional area different than or the same as the cross-sectional area of second protrusion 404. For example, first protrusion 404 can have a rectangular cross-sectional area and second protrusion 404 can have a circular cross-sectional area.

Protrusion 404 can define at least one opening 406. Opening 406 can include at least one height 412. Height 412 can be measured from the bottom of opening 406 to the tallest point of protrusion 404. Height 412 can be between 1 mm and 6 mm (height 412 can be greater than or less than this range). Height 412 can be equivalent to the height of protrusion 404. For example, protrusion 404 and opening 406 can both have a height of 2-6 mm (e.g., 4 mm). The bottom of opening 406 can extend at least partially above base plate 102 or landing zone 402. For example, protrusion 404 can have a height of 1-5 mm (e.g., 3 mm) and opening 406 can have a height 412 of 1-3mm (e.g., 2 mm) due to opening 406 extending 2.1-2.0 mm (e.g., 1 mm) above base plate 102 or landing zone 402.

Opening 406 can include a first opening 406 and a second opening 406. First opening 406 can include a first height 412 and second opening 406 can include a second height 412. First height 412 can be the same as or different than second height 412. For example, first height can be 2 mm and second height can be 4 mm. First opening 406 and second opening 406 can extend the same or different heights from base plate 102 or landing zone 402. For example, first opening 406 can extend 1 mm from base plate 102 and second opening 406 can be flush with base plate 102.

Heat sink 104 can include at least one fin 408. Fin 408 can extend from at least one surface of heat sink 104. For example, fin 408 can extend from the surface of heat sink 104 opposite the surface electronic device 106 is being sintered to. Heat sink 104 can include a plurality of fins 408 extending from at least one surface of heat sink 104. Fin 408 can include at least one height 410. Height 410 can be measured from the surface of heat sink 104 to the tallest point of fin 408. Height 410 can be between 1 mm to 6 mm (height 410 being greater than or less than this range). For example, height 410 can be 3 mm.

Fin 408 can include various shapes. For example, the cross-sectional area of fin 408 can include a polygon (e.g., triangle, square, rectangle, pentagon, etc.), a circle, an ellipsis, or a complex shape (e.g., a star, an irregular shape, etc.). Fin 408 can include one or more edges. The edges can include straight and curved edges. For example, fin 408 can include a straight edge and a curved edge opposite the straight edge.

Fin 408 can include a first fin 408 and a second fin 408. First fin 408 and second fin 408 can extend from the same or different surfaces of heat sink 104. For example, first fin 408 can extend from a first surface of heat sink 104 and second fin 408 can extend from a second surface of heat sink 104, the first surface opposite the second surface. First fin 408 can extend from a first heat sink 104 and second fin 408 can extend from a second heat sink 104, the first heat sink 104 separate from second heat sink 104.

First fin 408 can include a first height 410 and second fin 408 can include a second height 410. First height 410 can be the same as or different than second height 410. For example, first height 410 can be 5 mm and second height 410 can be 6 mm. First fin 408 can have a first cross-sectional area and second fin 408 can have a second cross-sectional area. The first cross-sectional area can be the same as or different from the second cross-sectional area. For example, first fin 408 can have a triangular cross-sectional area and second fin 408 can have a pentagon shaped cross-sectional area.

Opening 406 can receive at least one fin 408 of heat sink 104. For example, heat sink 104 can be lowered onto base plate 102 such that fin 408 can be inserted into opening 406. Fin 408 can have a different cross-sectional area than protrusion 404. For example, Fin 408 can have a circular cross-sectional area and protrusion 404 can have a square cross-sectional area. Height 410 of fin 408 can be greater than or less than the height of protrusion 404 or height 412 of opening 406. For example, height 412 can be 5 mm and height 410 can be 4 mm. Height 412 can be between. 1 mm and 0.5 mm greater than height 410. The difference between height 412 and height 410 can also be greater than or less than 0.1 mm and 0.5 mm.

Opening 406 receiving fin 408 can result in at least one gap 414. For example, height 412 can be greater than height 410 resulting in gap 414 being disposed between fin 408 and the bottom of opening 406. Gap 414 can have a height between 0.1 mm and 0.5 mm (Gap 414 can also have a height greater than or less than this range). Gap 414 can be an air gap where no solid material is disposed.

First opening 406 can receive first fin 408 and second opening 406 can receive second fin 408. First fin 408 and second fin 408 can be a part of the same or different heat sinks 104. For example, first opening 406 can receive first fin 408 of first heat sink 104 and second opening 406 can receive second fin 408 of first heat sink 104. First opening 406 can receive first fin 408 of first heat sink 104 and second opening 406 can receive second fin 408 of second heat sink 104. First opening 406 receiving first fin 408 can result in a first gap 414 and second opening 406 receiving second fin 408 can result in a second gap 414.

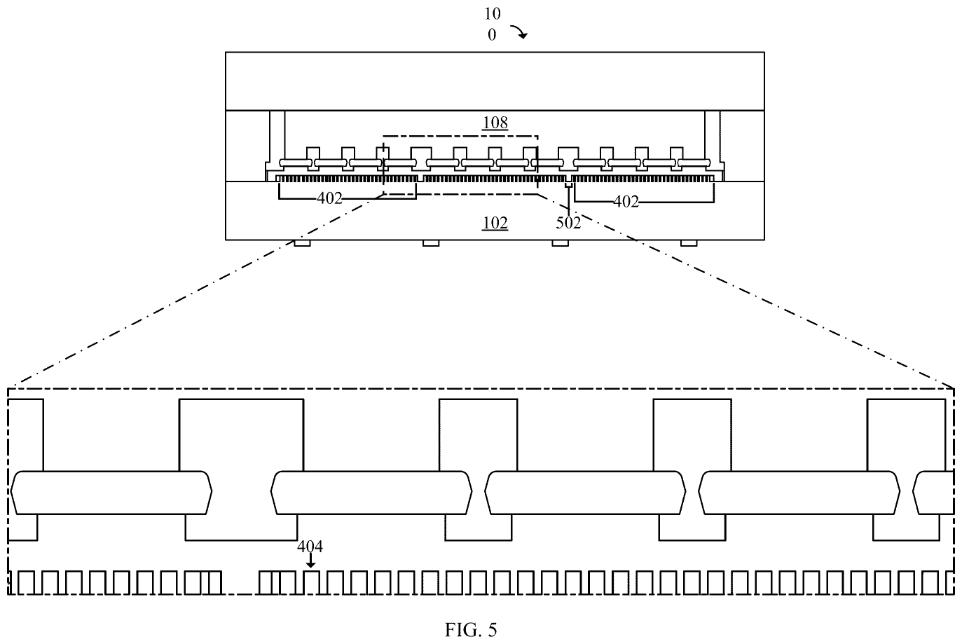

FIG. 5, among others, depicts an example of system 100 to assist in pressure sintering. First landing zone 402 and second landing zone 402 can be a part of the same base plate 102. First landing zone 402 and second landing zone 402 can be separated by a space 502. Space 502 can have a width equal to the width of protrusions 404. Space 502 can have a width greater than or less than the width of protrusions 404. First landing zone 402 and second landing zone 402 can be a part of different base plates 102. For example, first landing zone 402 can be a part of a first base plate 102 and second landing zone 402 can be a part of second base plate 102. Electronic device 106 can be coupled with first landing zone 402 or second landing zone 402 using the same press tool 108.

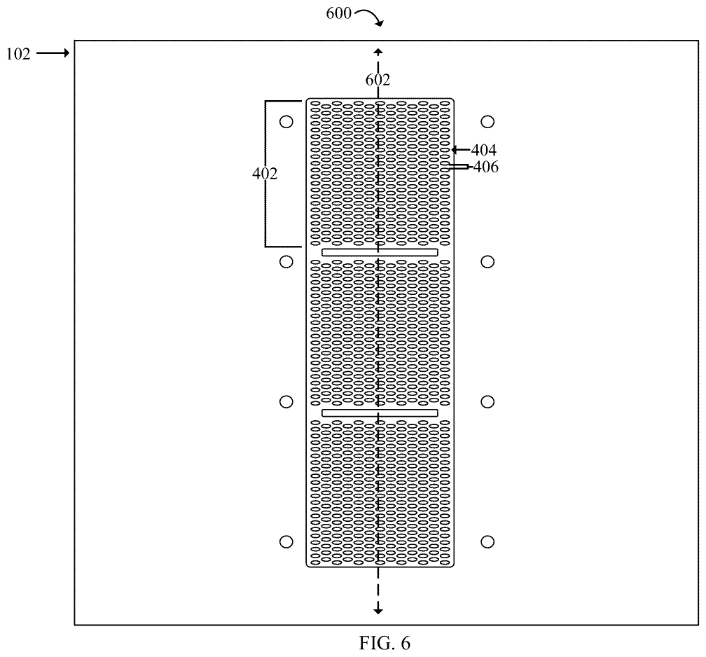

FIG. 6, among others, depicts an example of sintering apparatus 600. First landing zone 402 and second landing zone 402 can be disposed on at least on axis 602. Axis 602 can run vertically or horizontally across base plate 102. For example, first landing zone 402 and second landing zone 402 can be disposed in a line on axis 602. First landing zone 402 can be disposed on a first axis 602 and second landing zone 402 can be disposed on a second axis 602. First axis 602 can be parallel or perpendicular with second axis 602.

Protrusion 404 can at least partially define opening 406. For example, protrusion 404 and opening 406 can both be disposed on axis 602. First protrusion 404 and second protrusion 404 can at least partially define first opening 406. First opening 406 can be between first protrusion 404 and second protrusion 404. For example, first protrusion 404 and second protrusion 404 can both be disposed on axis 602 and first opening 406 can be disposed between first protrusion 404 and second protrusion 404. First protrusion 404 can be disposed on first axis 602, second protrusion 404 can be disposed on second axis 602, and first opening 406 can be disposed on first axis 602, second axis 602, or a third axis 602. Third axis 602 can be perpendicular or parallel with first axis 602 or second axis 602. Second opening 406 can at least partially define second opening 406. Second opening 406 can be disposed on the same or different axis 602 as first opening 406.

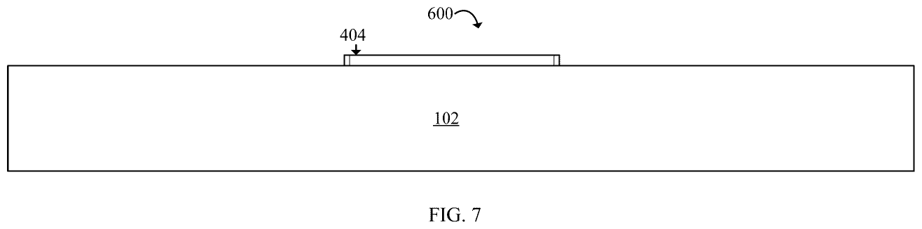

FIG. 7, among others, depicts an example of sintering apparatus 600. Landing zone 402 can extend from at least one face of base plate 102. For example, landing zone 402 can extend between a height of 1 mm to 6 mm off of base plate 102 (as well as a height greater than or less than this range). Landing zone 402 can be flush with base plate 102.

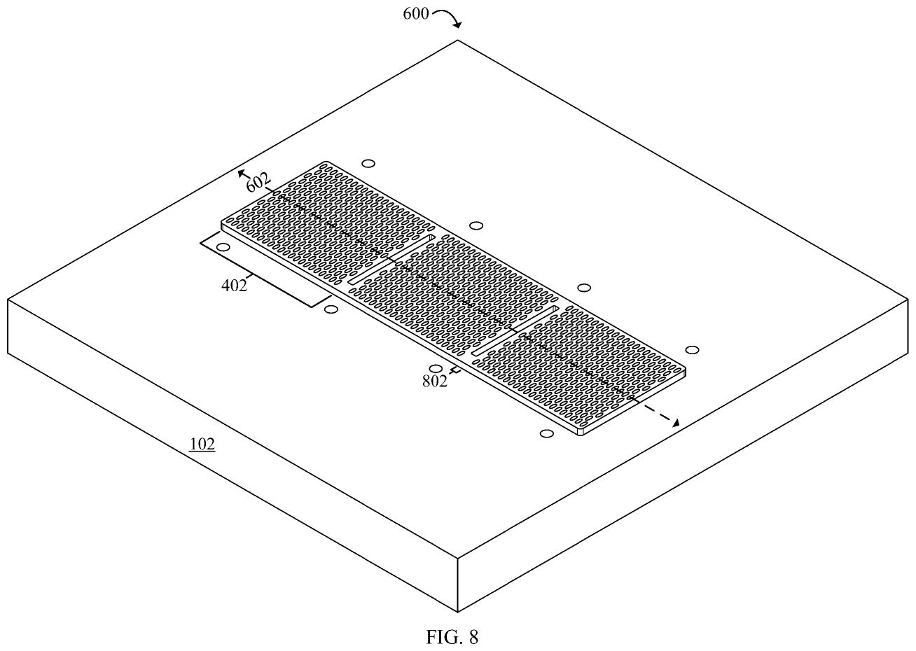

FIG. 8, among others, depicts an example of sintering apparatus 600. One or more landing zones 402 can be separated by at least one gap 802. For example, a first gap 802 can be disposed between first landing zone 402 and second landing zone 402 and a second gap 802 can be disposed between second landing zone 402 and third landing zone 402. Gap 802 can be disposed on axis 602. For example, gap 802 can be disposed between first landing zone 402 and second landing zone along axis 602.

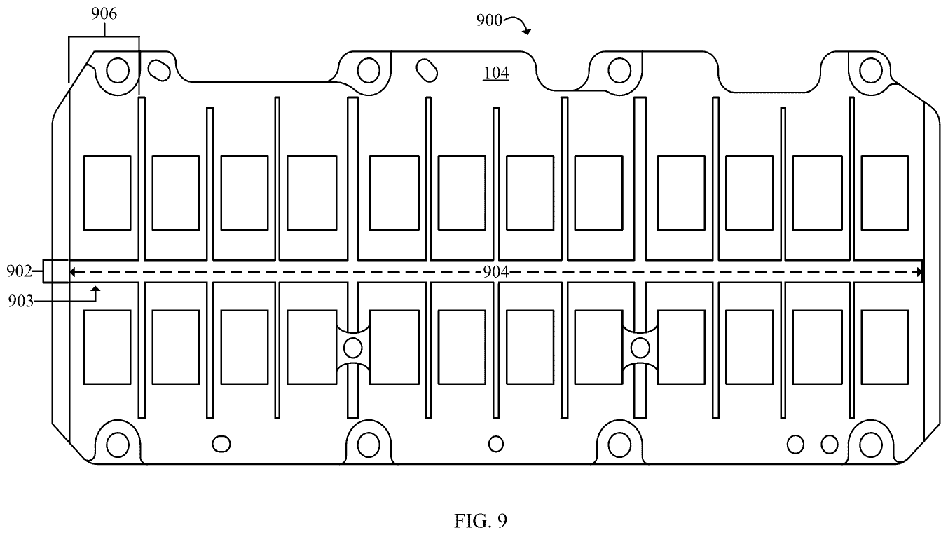

FIG. 9, among others, depicts an example of heat sink 900. Heat sink 900 can include heat sink 104. Heat sink 104 can include heat sink 900. Heat sink 900 can include at least one rib 902. Rib 902 can be a raised section of heat sink 900. For example, rib 902 can include a thickness greater than the thickness of the rest of heat sink 900. Rib 902 can include a variety of materials, for example, rib 902 can include metal (e.g., copper, aluminum, etc.) or non-metal materials (e.g., polymers, ceramics, etc.). Rib 902 can include a different material from the rest of heat sink 900. For example, heat sink 900 can include copper and rib 902 can include ceramics. Rib 902 can be disposed on at least one axis 904 of heat sink 900.

Rib 902 can include a first rib 902 and a second rib 902. First rib 902 and second rib 902 can both be disposed on axis 904, with a gap separating the two ribs. First rib 902 can be on a first axis 904 and second rib 902 can be on a second axis 904. First axis 904 can be parallel or perpendicular with second axis 904. First rib 902 and second rib 902 can include different thicknesses. For example, first rib 902 can be thicker than second rib 902. First rib 902 and second rib 902 can include different materials. For example, first rib 902 can include copper and second rib 902 can include a polymer.

Rib 902 can include at least one side 903. Side 903 can be parallel with axis 904. Side 903 can be defined by at least one edge of rib 902. For example, rib 902 can be disposed along axis 904 and side 903 can be defined by an edge of rib 902 parallel with axis 904. Rib 902 can include a first side 903 and a second side 903. First side 903 can be opposite to second side 903. For example, rib 902 can be disposed along axis 904 with two edges running parallel with axis 904. First side 903 can be defined by the first edge parallel with axis 904 and second side 903 can be defined by the second edge parallel with axis 904.

Heat sink 900 can include at least one section 906. Section 906 can take up part of heat sink 900. For example, section 906 can take up part of the surface area up at least one face of heat sink 900. Section 906 can take up between a quarter to three quarters of the surface area of at least one face of heat sink 900. Section 906 can also take up a greater or lesser amount of the surface area of at least one face of heat sink 900 than this range.

Section 906 can include a first section 906 and second section 906. First section 906 can take up a different amount of the surface area of at least one face of heat sink 900 than second section 906. For example, first section 906 can take up half of the surface area of a first face of heat sink 900 and second section 906 can take up a quarter of the surface area of the first face of heat sink 900. Second section 906 can be a sub section of first section 906. For example, first section 906 can take up half of the surface area of a first face of heat sink 900 and second section 906 can take up a quarter of the surface area of the first face of heat sink 900 taken up by first section 906.

Rib 902 can at least partially define section 906. Section 906 can be disposed on at least one side 903 of rib 902. For example, rib 902 be disposed on axis 904, which can run horizontally down the middle of heat sink 900. First section 906 can be disposed on first side 903 of rib 902 and second section 906 can be disposed on second side 903 of rib 902. First section 906 and second section 906 can be disposed on the same side 903 of rib 902.

First rib 902 and second rib 902 can at least partially define section 906. For example, second rib 902 can be perpendicular or parallel to first rib 902 and section 906 can be disposed between first rib 902 and second rib 902. First section 906 and second section 906 can be at least partially defined by first rib 902 or second rib 902. For example, first section 906 and second section 906 can be on the same side 903 of first rib 902 and on the same or opposite sides 903 of second rib 902. First section 906 and second section 906 can be on opposite sides 903 of first rib 902 and on the same or opposite sides 903 of second rib 902.

Heat sink 900 can include a plurality of ribs 902 perpendicular or parallel with first rib 902. The plurality of ribs 902 can extend from the first side 903 of first rib 902 to the second side 903 of first rib 902. Each rib 902 of the plurality of ribs 902 can define at least one section 906 of a plurality of sections 906. For example, each side 903 of each rib 902 of the plurality of ribs 902 can define at least one section 906 of the plurality of sections 906. A first rib 902 of the plurality of ribs 902 can at least partially define a first section 906 on a first side 903 and a second section 906 on a second side 903. A second rib 902 of the plurality of ribs can at least partially define the second section 906 of a first side 903 and a third section 906 on a second side 903.

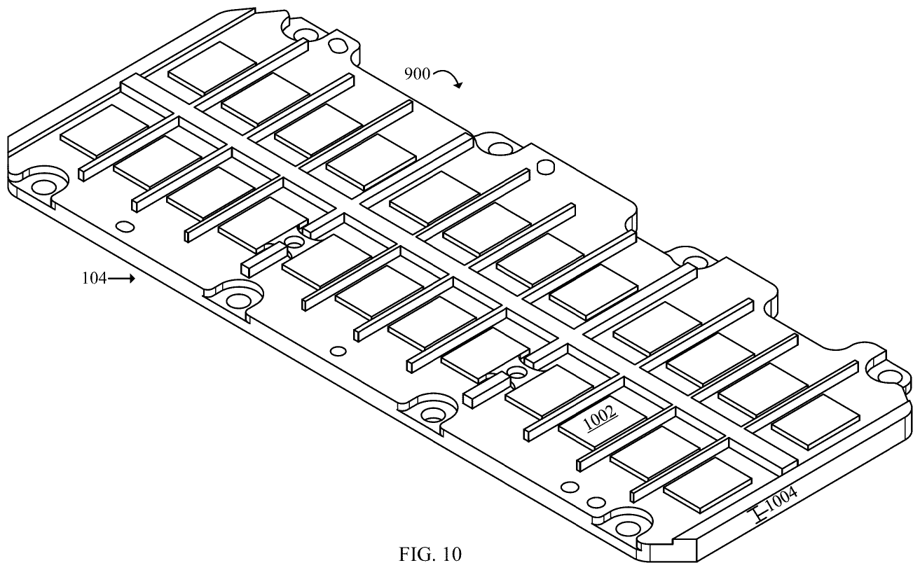

FIG. 10, among others, depicts an example of heat sink 900. Heat sink 900 can include at least one area 1002. Area 1002 can extend from or be flushed with at least one surface of heat sink 900. For example, area 1002 can extend from a first surface of heat sink 900, the first surface opposite of a second surface with at least one fin 408 extending from it.

Area 1002 can include at least one thickness 1004. The thickness 1004 can be equivalent to the height of area 1002. For example, area 1002 can be flush with heat sink 900, such that area 1002 has the same thickness 1004 as heat sink 900. Area 1002 can extend from heat sink 900, such that area 1002 has a thickness 1004 greater than heat sink 900.

Area 1002 can include various shapes. For example, the cross-sectional area of area 1002 can include a polygon (e.g., triangle, square, rectangle, pentagon, etc.), a circle, an ellipsis, or a complex shape (e.g., a star, an irregular shape, etc.). Area 1002 can include one or more edges. The edges can include straight and curved edges. For example, Area 1002 can include a straight edge and a curved edge opposite the straight edge.

Area 1002 can include a first area 1002 and a second area 1002. First area 1002 and second area 1002 can include the same thickness 1004. First area 1002 can include a first thickness 1004 and second area 1002 can include a second thickness 1004, where the first thickness 1004 is greater or less than the second thickness 1004. First thickness 1004 can be at least 30% thicker than second thickness 1004. Second thickness 1004 can be at least 30% thicker than second thickness 1004. First thickness 1004 can be between 30% to 70% thicker than second thickness 1004 (first thickness 1004 can also be greater than or less than this range). Second thickness 1004 can be between 30% to 70% thicker than first thickness 1004 (second thickness 1004 can also be greater than or less than this range).

First area 1002 and second area 1002 can extend from the same or different surfaces of heat sink 900. First area 1002 and second area 1002 can include the same or different shape. For example, first area 1002 can include a triangular cross-sectional area and second area 1002 can include a rectangular cross-sectional area. Second area 1002 can encompass first area 1002. Second area 1002 can surround first area 1002 on a surface of heat sink 900. For example, second area 1002 can surround first area 1002 on the top-most surface of heat sink 900.

Area 1002 can include a third area 1002 and a fourth area 1002. Third area 1002 and fourth area 1002 can include the same thickness 1004. Third area 1002 can include a third thickness 1004 and fourth area 1002 can include a fourth thickness 1004, where the third thickness 1004 is greater or less than the fourth thickness 1004. Third thickness 1004 can be at least 40% thicker than fourth thickness 1004. Third thickness 1004 can be at least 40% thicker than fourth thickness 1004. Third thickness 1004 can be between 30% to 40% thicker than fourth thickness 1004 (third thickness 1004 can also be greater than or less than this range). Fourth thickness 1004 can be between 30% to 40% thicker than third thickness 1004 (fourth thickness 1004 can also be greater than or less than this range).

One or more of the first thickness 1004, second thickness 1004, third thickness 1004, and fourth thickness 1004 can be equivalent. For example, first thickness 1004 can equal third thickness 1004 and second thickness 1004 can equal fourth thickness 1004. First thickness 1004, second thickness 1004, third thickness 1004, and fourth thickness 1004 can all include different thicknesses 1004.

First area 1002, second area 1002, third area 1002, and fourth area 1002 can extend from the same or different surfaces of heat sink 900. First area 1002, second area 1002, third area 1002, and fourth area 1002 can include the same or different shape. For example, first area 1002 and second area 1002 can include a triangular cross-sectional area, second area 1002 and fourth area can include a rectangular cross-sectional area. At least one of the first area 1002, second area 1002, third area 1002, and fourth area 1002 can encompass at least one of first area 1002, second area 1002, third area 1002, and fourth area 1002. For example, second area 1002 can encompass first area 1002 and fourth area 1002 can encompass third area 1002. At least one of First area 1002, second area 1002, third area 1002, and fourth area 1002 can surround at least one of First area 1002, second area 1002, third area 1002, and fourth area 1002 on a surface of heat sink 900. For example, second area 1002 can surround first area 1002 and fourth area 1002 can surround third area 1002 on the top-most surface of heat sink 900.

Section 906 can include area 1002. First section 906 and second section 906 can include at least one of first area 1002, second area 1002, third area 1002, and fourth area 1002. For example, first section 906 can include first area 1002 and second area 1002 and second section 906 can include third area 1002 and second area 1002. Each of the plurality of sections 906 can include one or more areas 1002.

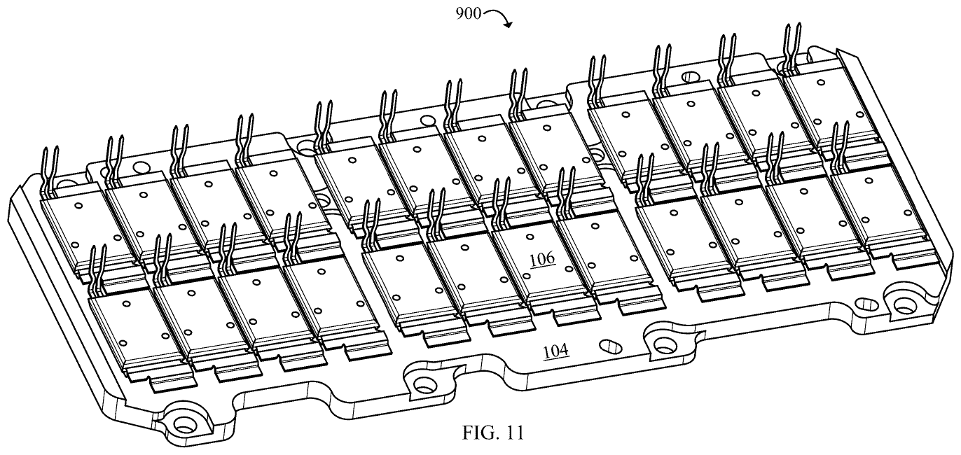

FIG. 11, among others, depicts an example of heat sink 900. Heat sink 900 can include at least one electronic device 106. Electronic device 106 can be sintered with at least one area 1002 of at least one section 906 of heat sink 900 using a silver paste (e.g., a green body). For example, a first electronic device 106 can be sintered to first area 1002 using the silver paste and a second electronic device 106 can be sintered to third area 1002 using the silver paste.

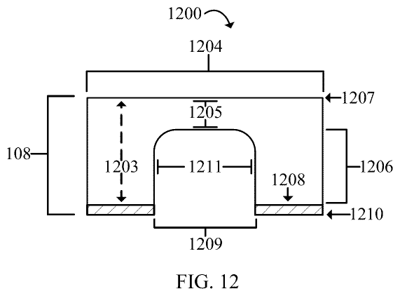

FIG. 12, among others, depicts an example of sintering apparatus 1200. Sintering apparatus 1200 can include at least one press tool 108. Press tool 108 can include at least one body 1204 and at least one height 1205. Body 1204 can include a first height 1205 and a variety of shapes. For example, Body 1204 can be a regular polyhedral solid (e.g., a cube, a tetrahedron, etc.) including one or more flat polygonal faces, straight edges, and vertices. Body 1204 can be an irregular polyhedral solid including one or more faces of a first shape and one or more faces of a second shape, such as an irregular pyramid with one or more faces that are triangular and one or more faces that are rectangular. Body 1204 can be a non-polyhedral solid (e.g., a sphere, an ellipsoid, a cylinder, etc.) including one or more curved surfaces or edges. For example, body 1204 can be a rectangular prism. Body 1204 can be coupled with plate 112.

Body 1204 can include at least one protrusion 1206. Protrusion 1206 can extend from at least one surface of body 1204. For example, protrusion 1206 can extend from a first surface of body 1204, the first surface opposite of a second surface of body 1204 coupled with plate 112. Protrusion 1206 can extend from at least one lateral edge 1207 of body 1204. Protrusion 1206 can be disposed along at least one axis 1203 of press tool 108 or body 1204. Axis 1203 can run vertically or horizontally across one or more faces of press tool 108 or body 1204.

Protrusion 1206 can include various shapes. For example, the cross-sectional area of protrusion 1206 can include a polygon (e.g., triangle, square, rectangle, pentagon, etc.), a circle, an ellipsis, or a complex shape (e.g., a star, an irregular shape, etc.). Protrusion 1206 can include one or more edges. The edges can include straight and curved edges. For example, protrusion 404 can include a straight edge and a curved edge opposite the straight edge.

Body 1204 and protrusion 1206 can include one or more materials. The one or more materials can include various metals (e.g., aluminum, alloy steel, tin, etc.), non-metals, woods, polymers, for example. For example, body 1204 can be made of wood and protrusion 1206 can be made of aluminum. Protrusion 1206 can be an integral part of body 1204. For example, protrusion 1206 and body 1204 can be one continuous component.

Protrusion 1206 can include a first protrusion 1206 and a second protrusion 1206. First protrusion 1206 and second protrusion 1206 can extend from the same surface of body 1204. First protrusion 1206 can extend from a first lateral edge 1207 of body 1204 and second protrusion can extend form a second lateral edge 1207 of body 1204, the first lateral edge 1207 parallel to the second lateral edge 1207. First protrusion 1206 can be disposed along a first axis 1203 and second protrusion 1206 can be disposed along a second axis 1203. First axis 1203 can be parallel or perpendicular with second axis 1203.

First protrusion 1206 can include a first cross-sectional area and second protrusion 1206 can include a second cross-sectional area. For example, first protrusion 1206 can include a square cross-sectional area and second protrusion 1206 can include a circular cross-sectional area.

Protrusion 1206 can at least partially define at least one gap 1209. Gap 1209 can have a third height 1205. Third height 1205 can be equal to first height 1205 of body 1204, First height 1205 can be greater than first height 1205 of body 1204 and less than second height 1205 of protrusion 1206. Gap 1209 can be defined by a straight or curved edge where body 1204 meets protrusion 1206. Gap 1209 can include at least one width 1211. Width 1211 can be the distance between one or more protrusion 1206 at least partially defining gap 1209.

Gap 1209 can be at least partially defined by first protrusion 1206 or second protrusion 1206. For example, gap 1209 can be disposed between first protrusion 1206 and second protrusion 1206. Gap 1209 can be disposed between first lateral edge 1207 and second lateral edge 1207. Gap 1209 can be disposed on a third lateral edge 1207 perpendicular to the first lateral edge 1207 and the second lateral edge 1207. Gap 1209 can be disposed along first lateral edge 1207 or second lateral edge 1207.

Gap 1209 can include a first gap 1209 and a second gap 1209. First gap 1209 can be at least partially defined by first protrusion 1206 and second protrusion 1206. Second gap can be at least partially defined by second protrusion 1206. First gap 1209 can include a first width 1211 and second gap 1209 can include a second width 1211. First width 1211 can be equal with second width 1211. First width 1211 can be greater than or less than second width 1211.

Press tool 108 can include at least one fiber-reinforced polymer cap. Fiber-reinforced polymer cap 1208 can be coupled with protrusion 1206. Fiber-reinforced polymer cap 1208 can be coupled with at least one face of protrusion 1206. For example, fiber-reinforced polymer cap 1208 can be coupled with a bottom face of protrusion 1206. Fiber-reinforced polymer cap 1208 can include a cross-section area the same as or different from the cross-sectional area of protrusion 1206. Fiber-reinforced polymer cap 1208 can include a height 1205. Height 1205 of fiber-reinforced polymer cap 1208 can be in a range of 0.5 mm to 3.5 mm. Height 1205 of fiber-reinforced polymer cap 1208 can also be greater than or less than this range. For example, Height 1205 of fiber-reinforced polymer cap 1208 can be in a range of 0.9 mm to 2.9 mm.

Fiber-reinforced polymer cap 1208 can contact at least one electronic device 106 to sinter electronic device 106 with at least one heat sink 104. For example, plate 112 can lower press tool 108 toward electronic device 106 causing fiber-reinforced polymer cap 1208 to contact electronic device 106. Fiber-reinforced polymer cap 1208 can apply a pressure to a first face of electronic device 106. The cross-sectional area of fiber-reinforced polymer cap 1208 can be equal to the cross-sectional area of the first face of electronic device 106. The cross-sectional area of fiber-reinforced polymer cap 1208 can be greater than or less than the cross-sectional area of the first face of electronic device 106.

Fiber-reinforced polymer cap 1208 can make contact with electronic device 106 at contact point 1210. Contact point 1210 can be at least one face of fiber-reinforced polymer cap 1208. For example, contact point 1210 can be the face of fiber-reinforced polymer cap 1208 that contacts electronic device 106. Fiber-reinforced polymer cap 1208 can be configured to apply a pressure to electronic device 106.

The fiber-reinforced polymer cap 1208 can have a first cross-sectional area, the electronic device 106 can have a second cross sectional area at contact point 1210. The second cross-sectional area can be equal to the first cross-sectional area. The second cross-sectional area can be less than or greater than the first cross-sectional area.

Fiber-reinforced polymer cap 1208 can include a start position and an end position. Fiber-reinforced polymer cap 1208 can be in the start position when not in contact with electronic device 106. Fiber-reinforced polymer cap 1208 can be in the end position when in contact with electronic device 106. Fiber-reinforced polymer cap 1208 can compress to the end position as fiber-reinforced polymer cap 1208 contacts electronic device 106. Height 1205 of fiber-reinforced polymer cap 1208 can be greater in the start position than the end position. Height 1205 of fiber-reinforced polymer cap 1208 can be in a range of 0.1 mm to 1.9 mm (or greater than or less than this range) less or greater in end position than the start position.

First protrusion 1206 can be coupled with a first fiber-reinforced polymer cap 1208 and second protrusion 1206 can be coupled with a second fiber-reinforced polymer cap 1208. First fiber-reinforced polymer cap 1208 and second fiber-reinforced polymer cap 1208 can contact the same electronic device 106 to sinter the electronic device 106 with heat sink 104. First fiber-reinforced polymer cap 1208 can contact a first electronic device 106 to sinter first electronic device 106 with heat sink 104 and second fiber-reinforced polymer cap 1208 can contact a second electronic device 106 to sinter second electronic device with heat sink 104. First fiber-reinforced polymer cap 1208 can contact a first electronic device 106 to sinter first electronic device 106 with a first heat sink 104 and second fiber-reinforced polymer cap 1208 can contact a second electronic device 106 to sinter second electronic device with a second heat sink 104.

First fiber-reinforced polymer cap 1208 can by configured to apply a first pressure to first electronic device 106. Second fiber-reinforced polymer cap 1208 can be configured to apply a second pressure to second electronic device 106. The first pressure and the second pressure can be equal. The first pressure can be greater than or less than the second pressure. The first pressure and the second pressure can vary between 5% and 25%. The first pressure and the second pressure can vary by a value greater than or less than this range. For example, the first pressure can vary from the second pressure by less than 15%. The second pressure can vary from the first pressure by less than 10%.

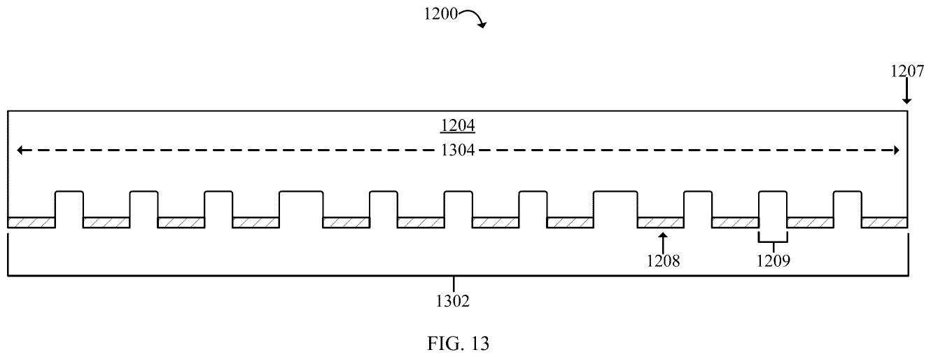

FIG. 13, among others, depicts an example of sintering apparatus 1200. Protrusion 1206 can include a plurality of protrusions 1206. Plurality of protrusions 1206 can include between 2 and 20 protrusions 1206 (Plurality of protrusions 1206 can include more or less protrusions 1206 than this range). Plurality of protrusions 1206 can include first protrusion 1206 or second protrusion 1206.

Plurality of protrusions 1206 can be arrange in row 1302 along lateral edge 1207 or along at least one length 1304 of body 1204. Length 1304 can be parallel with at least one edge of body 1204. For example, length 1304 can be parallel with lateral edge 1207.

Each protrusion in plurality of protrusion 1206 can partially define one or more gaps 1209 of a plurality of gaps 1209. For example, a first protrusion 1206 of plurality of protrusions 1206 can at least partially define a first gap 1209 of plurality of gaps 1209. A second protrusion 1206 of plurality of protrusions 1206 can at least partially define first gap 1209 and a second gap 1209 of the plurality of gaps 1209.

Each protrusion 1206 in plurality of protrusions 1206 can include at least one fiber-reinforced polymer cap.

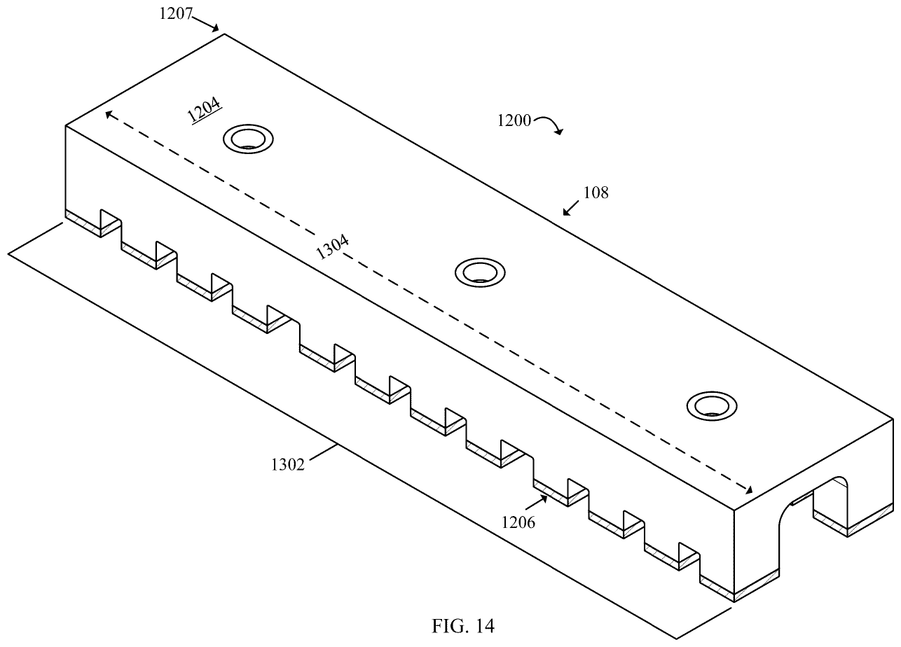

FIG. 14, among others, depicts an example of sintering apparatus 1200. Plurality of protrusions 1206 can include a first plurality of protrusions 1206 and a second plurality of protrusions 1206. First plurality of protrusions 1206 can be arranged in a first row 1302 and second plurality of protrusions 1206 can be arranged in a second row 1302. The first row 1302 can be disposed along a first lateral edge 1207 or a first length 1304 of body 1204. The second row 1302 can be disposed along a second lateral edge 1207 or a second length 1304 of body 1204. The first lateral edge 1207 or first length 1304 can be parallel or perpendicular to second lateral edge 1207 or second length 1304. The first lateral edge 1207 or first length 1304 can be opposite to second lateral edge 1207 or second length 1304. For example, first plurality of protrusions 1206 can be arranged in first row 1302 along first length 1304 of body 1204. Second plurality of protrusions 1206 can be arranged in second row 1302 along second length 1304 of body 1204 opposite first length 1304 of body 1204.

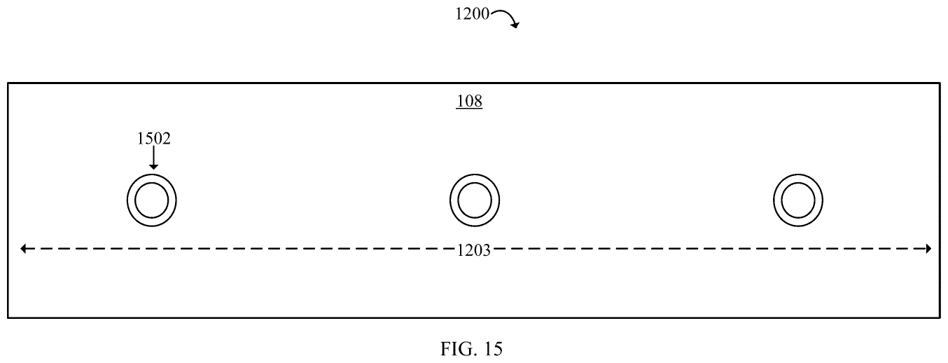

FIG. 15, among others, depicts an example of sintering apparatus 1200. Press tool 108 can include at least one fastening hole 1502. Fastening hole 1502 can traverse through body 1204 of press tool 108. Fastening hole 1502 can be used to couple body 1204 of press tool 108 to plate 112. Fastening hole 1502 can receive a fastener such as a screw, a nail, a bolt, or the like. Fastening hole 1502 can be disposed along at least one axis 1203 of body 1204.

Fastening hole 1502 can include a first fastening hole 1502, a second fastening hole 1502, and a third fastening hole 1502. First fastening hole 1502 can receive a first fastener to couple press tool 108 with plate 112. Second fastening hole 1502 can receive a second fastener to couple press tool 108 with plate 112. Third fastening hole 1502 can receive a third fastener to couple press tool 108 with plate 112. First fastening hole 1502, second fastening hole 1502, and third fastening hole can be disposed along the same axis 1203. First fastening hole 1502 can be disposed along a first axis 1203, second fastening hole 1502 can be disposed along a second axis 1203, and third fastening hole 1502 can be disposed along a third axis 1203. Any combination of first axis 1203, second axis 1203, and third axis 1203 can be parallel or perpendicular with each other. For example, first axis 1203 can be parallel with second axis 1203 and third axis can be perpendicular with first axis 1203.

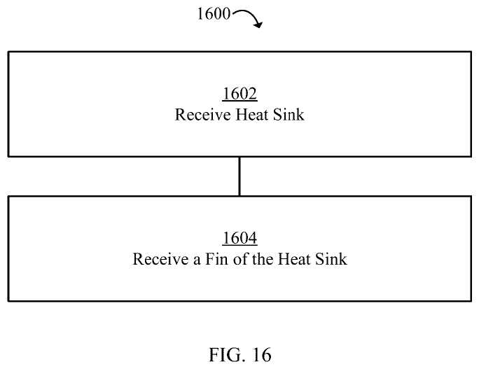

FIG. 16, among others, depicts an example of method 1600 of sintering an electronic device with a heat sink. Method 1600 can include at least one act of receiving heat sink 104 (e.g., act 1602). Base plate 102 can receive heat sink 104. For example, heat sink 104 can be lowered along a vertical axis onto base plate 102.

Method 1600 can include at least one act of receiving fin 408 of heat sink 104 (e.g. act 1604). For example, opening 406 at least partially defined by protrusion 404 of landing zone 402 can receive fin 408 of heat sink 104. As heat sink 104 is lowered along the vertical axis onto base plate 102, fin 408 can be received by opening 406.

Second fin 408 of heat sink 104 can be received by a second opening 406 at least partially defined by second protrusion 404. For example, as heat sink 104 is lowered along the vertical axis onto base plate 102, first fin 408 can be received by first opening 406 and second fin 408 can be received by second opening 406.

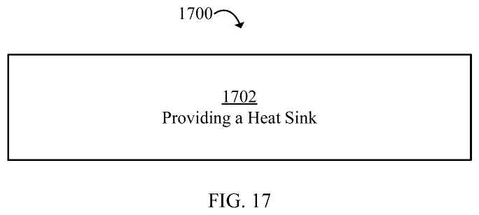

FIG. 17, among others, depicts an example of method 1700. Method 1700 can include at least one act of providing heat sink 104 (e.g., act 1702). For example, heat sink 104 can be lowered along a vertical axis onto base plate 102, such that a fin 408 of heat sink 104 is at least partially received by opening 406 defined by protrusion 404 of landing zone 402 of base plate 102.

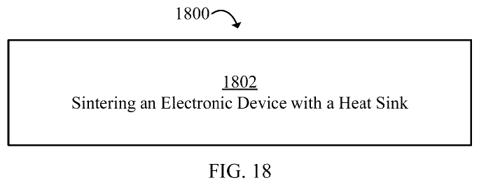

FIG. 18, among others, depicts an example of method 1800 of sintering an electronic device. Method 1800 can include at least one act of sintering electronic device 106 with a heat sink 104 (e.g., act 1802). For example, plate 112 can lower press tool 108 until plate 112 hits stoppers 110, at which point one or more fiber-reinforced polymer caps of press tool 108 can be in contact with electronic device 106 to sinter electronic device 106 with heat sink 104.

While acts or operations may be depicted in the drawings or described in a particular order, such operations are not required to be performed in the particular order shown or described, or in sequential order, and all depicted or described operations are not required to be performed. Actions described herein can be performed in different orders.

Having now described some illustrative implementations, it is apparent that the foregoing is illustrative and not limiting, having been presented by way of example. Features that are described herein in the context of separate implementations can also be implemented in combination in a single embodiment or implementation. Features that are described in the context of a single implementation can also be implemented in multiple implementations separately or in various sub-combinations.

The phraseology and terminology used herein is for the purpose of description and should not be regarded as limiting. The use of “including” “comprising” “having” “containing” “involving” “characterized by” “characterized in that” and variations thereof herein, is meant to encompass the items listed thereafter, equivalents thereof, and additional items, as well as alternate implementations consisting of the items listed thereafter exclusively. In one implementation, the systems and methods described herein consist of one, each combination of more than one, or all of the described elements, acts, or components.

Any references to implementations or elements or acts of the systems and methods herein referred to in the singular can include implementations including a plurality of these elements, and any references in plural to any implementation or element or act herein can include implementations including only a single element. References in the singular or plural form are not intended to limit the presently disclosed systems or methods, their components, acts, or elements to single or plural configurations. References to any act or element being based on any information, act or element may include implementations where the act or element is based at least in part on any information, act, or element.

References to “or” may be construed as inclusive so that any terms described using “or” may indicate any of a single, more than one, and all of the described terms. References to at least one of a conjunctive list of terms may be construed as an inclusive OR to indicate any of a single, more than one, and all of the described terms. For example, a reference to “at least one of ‘A’ and ‘B’” can include only ‘A’, only ‘B’, as well as both ‘A’ and ‘B’. Such references used in conjunction with “comprising” or other open terminology can include additional items.

Where technical features in the drawings, detailed description or any claim are followed by reference signs, the reference signs have been included to increase the intelligibility of the drawings, detailed description, and claims. Accordingly, neither the reference signs nor their absence have any limiting effect on the scope of any claim elements.

Modifications of described elements and acts such as variations in sizes, dimensions, structures, shapes and proportions of the various elements, values of parameters, mounting arrangements, use of materials, colors, orientations can occur without materially departing from the teachings and advantages of the subject matter disclosed herein. For example, elements shown as integrally formed can be constructed of multiple parts or elements, the position of elements can be reversed or otherwise varied, and the nature or number of discrete elements or positions can be altered or varied. Other substitutions, modifications, changes and omissions can also be made in the design, operating conditions and arrangement of the disclosed elements and operations without departing from the scope of the present disclosure.

The systems and methods described herein may be embodied in other specific forms without departing from the characteristics thereof. The foregoing implementations are illustrative rather than limiting of the described systems and methods. Scope of the systems and methods described herein is thus indicated by the appended claims, rather than the foregoing description, and changes that come within the meaning and range of equivalency of the claims are embraced therein.

Systems and methods described herein may be embodied in other specific forms without departing from the characteristics thereof. For example, descriptions of positive and negative electrical characteristics may be reversed. For example, elements described as negative elements can instead be configured as positive elements and elements described as positive elements can instead by configured as negative elements. Further relative parallel, perpendicular, vertical or other positioning or orientation descriptions include variations within +/−10% or +/−10 degrees of pure vertical, parallel or perpendicular positioning. References to “approximately,” “about” “substantially” or other terms of degree include variations of +/−10% from the given measurement, unit, or range unless explicitly indicated otherwise. Coupled elements can be electrically, mechanically, or physically coupled with one another directly or with intervening elements. Scope of the systems and methods described herein is thus indicated by the appended claims, rather than the foregoing description, and changes that come within the meaning and range of equivalency of the claims are embraced therein.

1.-20. (canceled)

21. A heat sink, comprising;
a rib;
a section at least partially defined by the rib; and
the section including a first area and a second area, the first area thicker than the second area.

22. The heat sink of claim 21, comprising:
the first area of the section of the heat sink being at least 40% thicker than the second area of the section of the heat sink.

23. The heat sink of claim 21, comprising:
the first area between 30% to 70% thicker than the second area.

24. The heat sink of claim 21, wherein the section is a first section, comprising:
a second section at least partially defined by the rib, the second section disposed on an opposite side of the rib relative to the first section; and
the second section including a third area and a fourth area, the third area thicker than the fourth area.

25. The heat sink of claim 21, wherein the section is a first section, comprising:
a second section on an opposite side of the rib than the first section, the second section including a third area and a fourth area, the third area thicker than the fourth area;
the first area and the third area having a same first thickness; and
the second area and the fourth area having a same second thickness.

26. The heat sink of claim 21, wherein the rib is a first rib, comprising:
a second rib perpendicular to the first rib, the second rib at least partially defining the section.

27. The heat sink of claim 21, wherein the rib is a first rib, and the section is a first section, comprising:
a second rib perpendicular to the first rib;
the first rib and the second rib at least partially defining the first section and a second section; and
the first section and the second section disposed a same side of the rib and disposed on opposite sides of the second rib.

28. The heat sink of claim 21, wherein the rib is a first rib and the section is a first section, comprising:
a second rib perpendicular to the first rib;
the first rib and the second rib at least partially defining the first section and a second section; and
the first section and the second section disposed a same side of the second rib and disposed on opposite sides of the first rib.

29. The heat sink of claim 21, comprising:
an electronic device sintered to the first area of the section using a silver paste.

30. The heat sink of claim 21, wherein the section is a first section, comprising:
a second section at least partially defined by the rib, the second section disposed on a same side of the rib relative to the first section; and
the second section including a third area and a fourth area, the third area thicker than the fourth area.

31. The heat sink of claim 21, wherein the rib is a first rib, and the section is a first section, comprising:
a second rib perpendicular to the first rib;
the first rib and the second rib at least partially defining the first section and a second section;
the second section including a third area and a fourth area, the third area thicker than the fourth area;
the first area and the third area having a same first thickness; and
the second area and the fourth area having a same second thickness.

32. The heat sink of claim 21, wherein the section is a first section, comprising:
a second section at least partially defined by the rib;
the second section including a third area and a fourth area, the third area thicker than the fourth area;
a first electronic device sintered to the first area using a silver paste; and
a second electronic device sintered to the third area using the silver paste.

33. The heat sink of claim 21, comprising:
the first area in a shape of a rectangle; and
the second area encompassing the first area.

34. The heat sink of claim 21, comprising:
the first area in a shape of a square; and
the second area surrounding the first area on a top surface of the heat sink.

35. The heat sink of claim 21, comprising:
the first area extending from a first surface of the heat sink; and
a fin extending from a second surface of the heat sink opposite the first surface.

36. The heat sink of claim 21, comprising:
a plurality of fins extending from a surface of the heat sink.

37. A method, comprising:
providing a heat sink, the heat sink including:
a rib;
a section at least partially defined by the rib; and
the section including a first area and a second area, the first area thicker than the second area.

38. The method of claim 37, wherein the section is a first section, the heat sink comprising:
a second section at least partially defined by the rib, the second section disposed on an opposite side of the rib relative to the first section; and
the second section including a third area and a fourth area, the third area thicker than the fourth area.

39. The method of claim 37, wherein the section is a first section, the heat sink comprising:
a second section at least partially defined by the rib, the second section disposed on a same side of the rib relative to the first section; and
the second section including a third area and a fourth area, the third area thicker than the fourth area.

40. The method of claim 37, wherein the section is a first section, comprising:
a second section at least partially defined by the rib;
the second section including a third area and a fourth area, the third area thicker than the fourth area;
a first electronic device sintered to the first area using a silver paste; and
a second electronic device sintered to the third area using the silver paste.

41.-60. (canceled)
